(19) United States
(12) Patent Application Publication
(10) Pub. No.: US 2024/0063041 A1
(43) Pub. Date: Feb. 22, 2024

(54) HEAVY-DUTY PROBE CARD TRANSFER AND LOADING DEVICE

(71) Applicants: Gosung engineering Co., Ltd, Hwaseong-si (KR); SK hynix Inc., Icheon-si (KR)

(72) Inventors: Ki Tae Kim, Osan-si (KR); Jung Shik LEE, Osan-si (KR); Dae Han KIM, Anyang-si (KR); WOON SEAP JANG, Icheon-si (KR); SANG KYUN PARK, Icheon-si (KR); DONG HYUG OH, Icheon-si (KR)

(21) Appl. No.: 18/451,838

(22) Filed: Aug. 18, 2023

(30) Foreign Application Priority Data
Aug. 19, 2022 (KR) 10-2022-0104221

(51) Int. Cl. H01L 21/677

(52) U.S. Cl. CPC H01L 21/67736; H01L 21/67706; H01L 21/6773

(57) ABSTRACT

Provided is a heavy-duty probe card transfer and loading device including a main body that moves along a set travel route, a loading arm assembly including an up-down unit coupled to the main body and configured to perform a lifting and lowering operation, a first arm drive unit rotatably coupled to the up-down unit, and a second arm drive unit rotatably coupled to the other end of the first arm drive unit, and a gripper unit rotatably coupled to the second arm drive part to grip a heavy-duty probe card and place the same on the main body.

### CROSS-REFERENCE TO RELATED APPLICATION

This application claims priority under 35 U.S.C. § 119 to Korean Patent Application No. 10-2022-0104221, filed in the Korean Intellectual Property Office on Aug. 19, 2022, the entire contents of which are hereby incorporated by reference.

### TECHNICAL FIELD

The disclosure relates to a high-duty probe card transfer and loading device. More specifically, the disclosure relates to a high-duty probe card transfer and loading device capable of picking up, transferring, and loading heavy-duty probe cards while moving along a set driving route, and thus capable of supplying expensive heavy-duty probe cards in a stable and timely manner, thus providing maximum production efficiency, and also is capable of unmanned transfer and loading without requiring the presence of a worker in place.

### BACKGROUND

In general, it is necessary that the probe cards are variously replaced or changed according to the semiconductor device being manufactured.

The replacement of the probe card is performed by a probe card replacement device provided in an inspection device, and supplying and settling the probe card in the probe card replacement device is manually performed by a worker.

However, in the case of heavy-duty probe cards that weigh from 25 kg to 40 kg, supplying and settling these probe cards for replacement requires the worker to carry a replacement probe card and directly settling it in the probe card replacement device, and the large diameter and heavy weight of the probe card is inevitably burdensome to the worker, and this inevitably increases the replacement time of the probe card, and the increased replacement time means that the working time for the inspection process of the probe card is increased, and subsequently reduced productivity of the probe card.

In addition, there is a risk that the worker may inadvertently impact the probe card as he is working with great effort, and this eventually causes damage or breakage of the probe card, resulting in a serious decrease in workability and productivity.

In addition, in a work line with a large number of inspection devices, there is a problem in that a separate work space for replacing the probe card should be secured for each inspection device when replacing the probe card, because it is necessary for the operator to separate the used probe card from the probe card replacement device near the side of the inspection device and supply and settle a new probe card.

It is to be noted that the background or related art described above is only for helping to understand the technical meaning of the present disclosure, and does not mean a technique widely known in the technical field to which the present disclosure pertains before the application of the present disclosure.

### SUMMARY

In order to solve the problems described above, an object of the present disclosure to provide a heavy-duty probe card transfer and loading device capable of picking up, transferring, and loading heavy-duty probe cards while moving along a set driving route, and thus capable of supplying expensive heavy-duty probe cards in a stable and timely manner, thus providing maximum production efficiency.

In addition, an object of the disclosure is to provide a high-duty probe card transfer and loading device capable of transferring and loading a heavy-duty probe card in a minimum work space for a driving route, since the disclosure is capable of unmanned transfer and loading of the heavy-duty probe card along a set autonomous driving route without requiring a worker to be placed.

It should be understood, however, that the scope of the present disclosure is not limited to the above and that the objects and effects which can be understood from the solution means and the embodiments of the present disclosure are also included therein even if not explicitly mentioned.

According to one embodiment of the disclosure for achieving the above object, a heavy-duty probe card transfer and loading device is provided, which may include a main body 100 that moves along a set travel route, a loading arm assembly 200 including an up-down unit 210 coupled to the main body 100 and configured to perform a lifting and lowering operation, a first arm drive unit 230 rotatably coupled to the up-down unit 210, and a second arm drive unit 250 rotatably coupled to the other end of the first arm drive unit 230, and a gripper unit 300 rotatably coupled to the second arm drive part 250 to grip a heavy-duty probe card and place the same on the main body 100.

The main body 100 may include a transfer body 110 including a transfer means 120 for moving along the travel route, a control main body 130 including a driving control unit for controlling driving of the probe card transfer and loading device, and a battery built therein, in which the loading arm assembly 200 is mounted to the control main body 130, a loading top plate 140 coupled to an upper portion of the control main body 130 and supporting the probe card so that the probe card can be seated in position, a mounting sensor 150 configured on the loading top plate 140 and sensing whether or not the probe card is seated and transmitting the sensed result to a drive control unit, and a charging unit 160 formed on the control main body unit 130 and configured to allow electrical connection of the battery and the docking device.

The control main body 130 may include a safety laser sensor 132 that recognizes an obstacle and allows the driving to be performed while avoiding the recognized obstacle, and a load arm motion search unit 134 that senses whether the load arm assembly 200 is operated or not so that an operating state of the load arm assembly 200 can be determined.

The control main body may further include a drive control unit that analyzes information transmitted from the safety laser sensor 132 and the load arm motion search unit 134 to generate route information about positions for withdrawing and replacing the probe card, and a transfer position for transferring the withdrawn probe card, and an operating module 139 that transmits a control signal for controlling the driving of the probe card transfer and loading device to the drive control unit.

The up-down unit may include a lifting motor 212 driven under the control of a drive control unit, a ball screw 214 lifted and lowered when the lifting motor is driven, a lifting guide panel 218 lifted and lowered when the ball screw 214 is operated and including a lifting shaft 220 configured at an upper central portion and connected to the first arm drive unit 230, and an LM guide member 216 that guides the lifting and lowering of the lifting guide panel 218 when the ball screw 214 is operated.

The first arm drive unit 230 may include a first arm drive housing 232 configured with a communication and control unit 242, a first arm rotating means 234 configured in front and rear portions of the first arm drive housing 232 and connected to the second arm drive unit 250 and the up-down unit 210, respectively, a rear-side connection drive 236 rotatably connected to the first arm rotating unit 234 and rotating the first arm drive housing 232, and a front-side connection drive 238 rotatably connected to the first arm rotating unit 234 and rotating the second arm drive unit 250.

The second arm drive unit 250 may include a second arm drive housing 252, an arm connection member 256 formed at a rear portion of the second arm drive housing 252 and connected to the rear-side connection drive 238, a gripper connection drive 258 formed on a front portion of the second arm drive housing 252 and to which the gripper unit 300 is rotatably coupled, and a second arm rotating means 254 for rotating the gripper connection drive 258.

The gripper unit 300 may include a gripper 340 that grips the heavy-duty probe card, a mounting frame 320 rotatably coupled to the second arm drive unit 250, and a vision camera 310 coupled to the mounting frame 320 and determining a gripping position of the gripper 340.

The mounting frame 320 may include a position guide frame 324 coupled to a front side end and mounted with a position control member 326 that adjusts the position of the gripper 340, and a gripper tip 328 slidably coupled to a lower end of the position guide frame 324 and to which the gripper 340 is coupled.

According to the embodiments of the disclosure, there is an effect of picking up, transferring, and loading heavy-duty probe cards while moving along a set driving route, and being capable of supplying expensive heavy-duty probe cards in a stable and timely manner, thus providing maximum production efficiency.

In addition, according to the embodiments of the disclosure, there is an effect of transferring and loading a heavy-duty probe card in a minimum work space for a driving route, since unmanned transfer and loading of the heavy-duty probe card along a set autonomous driving route is possible without requiring a worker to be placed.

Further, the various and beneficial advantages and effects of the present disclosure are not limited to the above description, and can be more easily understood in the course of describing a specific embodiment of the present disclosure.

### BRIEF DESCRIPTION OF THE DRAWINGS

The above and other objects, features and advantages of the present disclosure will be described with reference to the accompanying drawings described below, where similar reference numerals indicate similar elements, but not limited thereto, in which:

FIG. 1 is a perspective view of a high-duty probe card transfer and loading device according to an embodiment of the disclosure;

FIG. 2 is a side view of a high-duty probe card transfer and loading device according to an embodiment of the disclosure;

FIGS. 3 and 4 are front and rear views of a high-duty probe card transfer and loading device according to an embodiment of the disclosure;

FIG. 5 is a plan view of a high-duty probe card transfer and loading device according to an embodiment of the disclosure;

FIGS. 6 to 8 are views showing an up-down unit of a high-duty probe card transfer and loading device according to an embodiment of the disclosure;

FIGS. 9 and 10 are views showing a first arm drive unit of a high-duty probe card transfer and loading device according to an embodiment of the disclosure;

FIG. 11 is a view showing a second arm drive unit of a heavy-duty probe card transfer and loading device according to an embodiment of the disclosure; and

FIGS. 12 to 14 are views showing a gripper unit of a high-duty probe card transfer and loading device according to an embodiment of the disclosure.

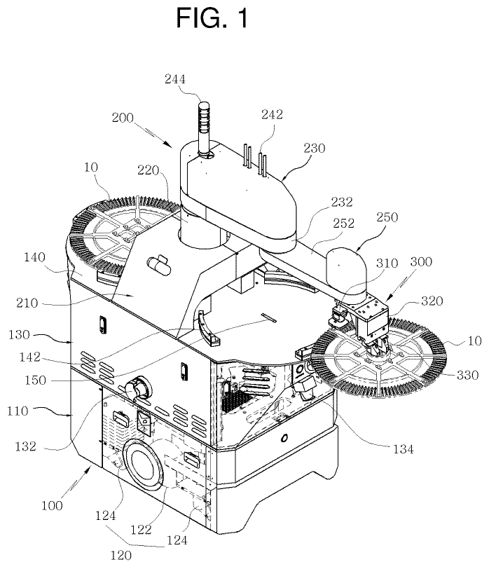

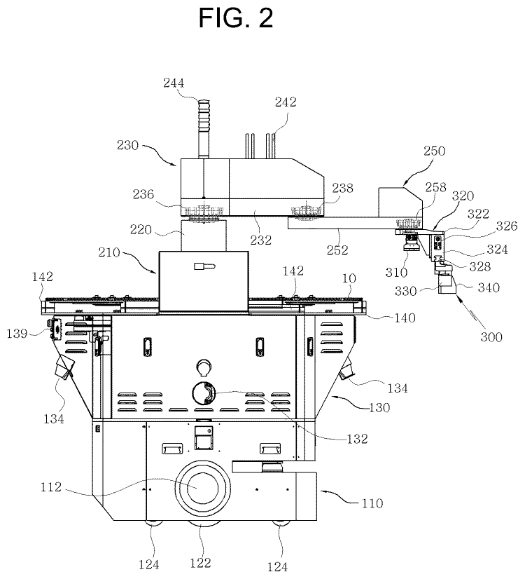

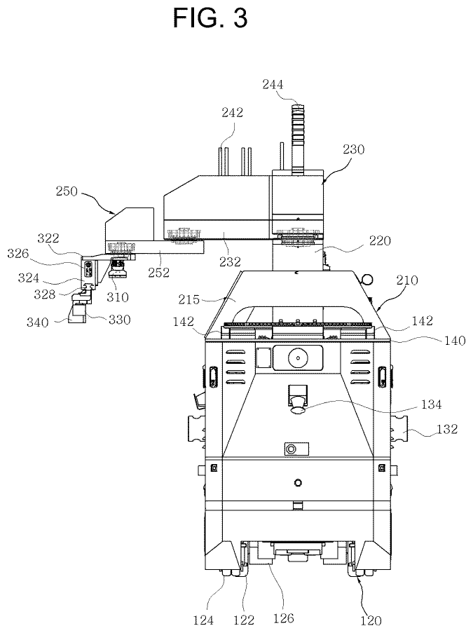

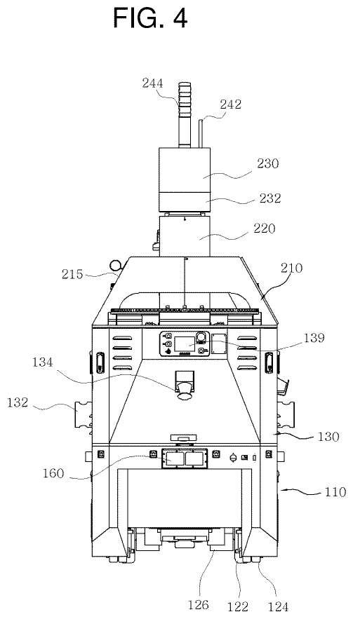

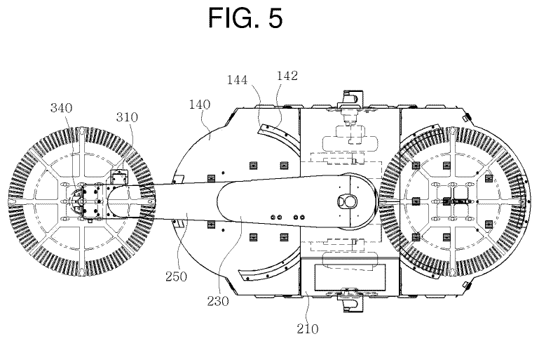

### DETAILED DESCRIPTION

Hereinafter, preferred embodiments of the present disclosure will be described in detail with reference to the accompanying drawings. It should be noted that, when adding reference numerals to the components shown in the drawings, the same components, whether they are illustrated in the same drawing or different drawings, will be denoted by the same reference numerals. In the following description of the present disclosure, a detailed description of known functions and configurations incorporated herein will be omitted when it may make the subject matter of the present disclosure rather unclear.

In addition, it is to be understood that, unless specifically stated to the contrary, the term “comprise”, “include”, or “have” as used herein may mean that a corresponding component can be inherently included, and therefore, should be construed as meaning that other components may be additionally included rather than excluding the same, and all terms including technical or scientific terms have the same meaning as commonly understood by one of ordinary skill in the art to which this disclosure belongs, unless otherwise defined. Further, in the description of the components of the present disclosure, “first,” “second,” “A,” “B,” “(a),” “(b)” may be used to identify the components. These are used to distinguish a component from another component, and used only for convenience of explanation, and the nature, sequence, or order of the corresponding component is not limited by these expressions. When a certain component is stated as being “connected” or “coupled” to another component, it is to be understood that there may be yet another intervening component “connected” or “coupled between the two components, although the two components may also be directly connected or coupled to each other.

Hereinafter, embodiments of the present invention will be described in detail with reference to the accompanying drawings.

As shown, a high-duty probe card transfer and loading device of the disclosure includes a main body 100 that moves in an autonomous driving manner to transfer the high-duty probe card and that supports the probe card to be seated thereon, an arm assembly 200 coupled to an upper portion of the main body 100 and withdrawing the probe card from the equipment, and transferring and loading the same, and a gripper unit 300 configured in the arm assembly 200 to recognize a position of the probe card and grip the recognized probe card.

The main body 100 includes a transfer body 110 including a transfer means 120 configured to move the probe card transfer and loading device of the disclosure, a control main body 130 including a drive control unit (not shown) that controls the driving of the probe card transfer and loading device and a battery (not shown) built therein, and a loading top plate 140 coupled to an upper portion of the control main body 130 and supporting the probe card so that the probe card can be seated in position.

The transfer body unit 110 includes a transfer means driving motor 126 that provides a predetermined rotational force under the control of the drive control unit, and first and second transfer means 122 and 124 coupled to the transfer means driving motor 126 to transfer the main body 100.

The transfer means driving motor 126 may include a known wheel motor, and may be configured to be coupled to each of the first and second transfer means 122 and 124 and provide a predetermined rotational force.

The first transfer means 122 may be configured on both sides of a lower portion of the transfer body 110 to change a direction of the main body 100. In addition, the second transfer means 124 may be configured on a front portion and a rear portion of the first transfer means 122 respectively to allow straight movement of the main body 100.

In addition, a light emitting unit 112 may be additionally configured on one side or both sides of the transfer body 110 to emit a predetermined light when the transfer means driving motor 126 is driven.

The control main body 130 may include a drive control unit configured on an upper portion of the transfer body 110 to control the driving of the transfer means driving motor 126 so that the main body 100, that is, the probe card transfer and loading device of the disclosure can be moved along a preset travel route, and may also include a battery built therein to supply power for driving the probe card transfer and loading device of the disclosure.

The control main body 130 includes a safety laser sensor 132 connected to the drive control unit through a network, and the safety laser sensor 132 is configured to recognize an obstacle during operation of the loading arm assembly 200 loaded with the prop card, and allow the driving to be performed while avoiding the recognized obstacle.

The safety laser sensor 132 may sense and generate route deviation information when the transfer means 120 configured in the transfer body 110 is deviated from the route set by the drive control unit and transmit the generated route deviation information to the drive control unit to control the driving of the transfer means 120.

The safety laser sensor 132 may be configured to recognize a recognition mark including predetermined route information, but is not limited thereto.

The safety laser sensor 132 may further perform a route search function to check whether movement is in conformity with the set route information while the probe card transfer and loading device is autonomously traveling, but is not limited thereto.

In addition, the control main body 130 includes a load arm motion search unit 134 that senses a motion of the loading arm assembly 200 and transmits a sensed motion signal of the loading arm assembly 200 to the drive control unit so that the motion of the loading arm assembly 200 can be determined.

In addition, the control main body 130 includes an operating module 139 that transmits a control signal for controlling the driving of the probe card transfer and loading device to the drive control unit.

The drive control unit may be configured to analyze the information transmitted from the safety laser sensor 132 and the load arm motion search unit 134 and generate route information about positions for withdrawing and replacing a probe card and a transfer position for transferring the withdrawn probe card, and transmit the generated route information to the operating module 139 for display.

Meanwhile, the drive control unit of the disclosure generates information about a route for the movement of the probe card transfer and loading device, and controls the driving of the transfer unit driving motor 126 based on the generated route information.

In addition, the drive control unit may be connected to the control module 139 through a network, and control the transfer means driving motor 126 so as to move the probe card transfer and loading device based on the route information manually input through the control module 139.

Meanwhile, the drive control unit of the disclosure may control the driving of the transfer means driving unit motor 126 in conjunction with the battery by receiving a charging request signal from the battery.

The drive control unit may store position information for charging power, and the position for charging power may be a position of a docking device electrically connected to a charging unit 160 to be described below.

In addition, the control main body 130 includes a mounting sensor 150 configured to be positioned at a center of the loading top plate 140, in which the mounting sensor 150 is connected to the drive control unit through a network to sense whether the probe card is seated, and is also configured to transmit the sensed signal to the drive control unit.

The mounting sensor 150 is configured to be positioned coaxially with a vision camera 310 of the gripper unit 300 to be described later and provide information on a position where the probe card is to be seated.

In addition, the control main body 130 additionally includes a charging unit 160 is formed on a rear portion, configured to be electrically connected to the battery and a docking device (not shown), respectively, and charge the battery when connected to the docking device.

Meanwhile, the probe card is seated on an upper surface of the control main body 130 of the disclosure, and the loading top plate 140 is coupled to support the seated probe card so that the probe card can be stably transferred.

The loading top plate 140 is configured on upper front and rear portions of the control main body 130, respectively, and configured such that the withdrawn probe card (used probe card) and the replacement probe card (unused probe card) are seated thereon, respectively.

The loading top plate 140 includes a mounting member 142 on which the probe card is seated and which includes a mounting jaw 144 formed thereon to fix the seated probe card so as to prevent the position of the probe card from being inadvertently deviated due to vibrations, impacts, and so on, which may be generated during autonomous driving of the probe card transfer and loading device.

There may be a plurality of mounting members 142 configured at equal intervals based on the center of the loading top plate 140, and a total of three mounting members 142 at 120 degree intervals are illustrated herein, although aspects are not limited thereto.

In addition, the control main body 130 of the disclosure may include an up-down unit 210 of the arm assembly 200, which will be described below, mounted thereon, and may be configured to support such that the drive control unit and the up-down unit 210 can be connected through a network and the driving of the up-down unit 210 is controlled according to the control of the drive control unit.

The arm assembly 200 includes an up-down unit 210 fixedly coupled to the control main body 130 and configured to perform a lifting and lowering operation under the control of the driving control unit, a first arm drive unit 230 rotatably coupled at one end with the up-down unit 210, and a second arm drive unit 250 rotatably coupled with the other end of the first arm drive unit 230 and coupled with, at a leading end thereof, the gripper unit 300.

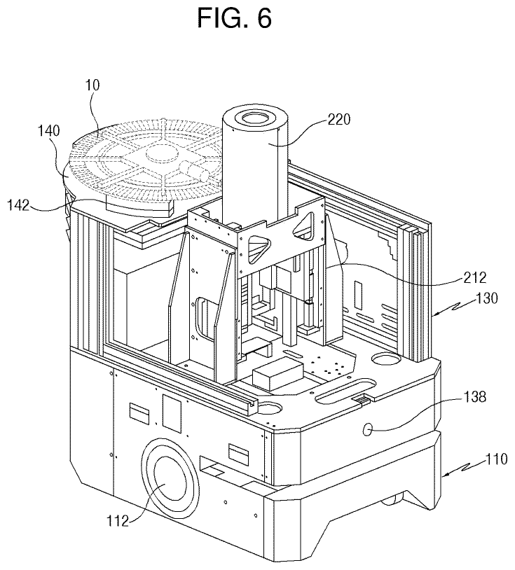

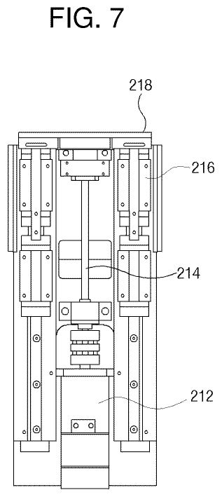

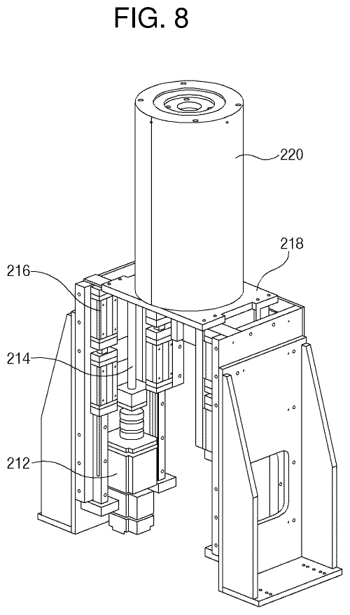

As shown in FIGS. 6 to 8, the up-down unit 210 is configured to perform the lifting and lowering operation so as to adjust the height of the first and second arm drive units 230 and the gripper unit 300 connected to the second arm drive unit 230, and support the rotation operation of the first arm drive unit 230 in an X-axis direction, that is, in left-right direction.

The up-down unit 210 includes lifting motors 212 configured on both inner sides, coupled to positions corresponding to each other, and driven under the control of the drive control unit, ball screws 214 for performing lifting and lowering operation when the lifting motors 212 are driven, a lifting guide panel 218 lifted and lowered when the ball screws 214 is operated and including a lift shaft 220 configured at an upper central portion and connected to the first arm drive unit 230, and LM guide members 216 configured on both sides of the lifting motor 212 to guide the lifting guide panel 218 to be precisely and stably lifted and lowered when the ball screws 214 are operated.

The lifting shaft 220 includes a drive fixing part configured at an upper end, into which a rear-side connection drive 236 of the first arm drive unit 230 is inserted and fixed.

In addition, the up-down unit 210 may further include a protective guide 215 that protects the worker during the lifting and lowering operation of the lifting shaft 220 and supports the components of the up-down unit 210 housed therein.

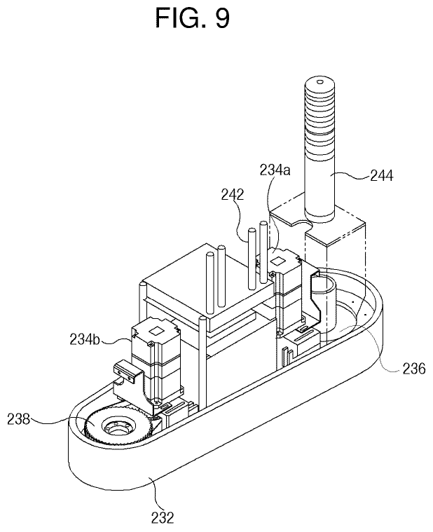

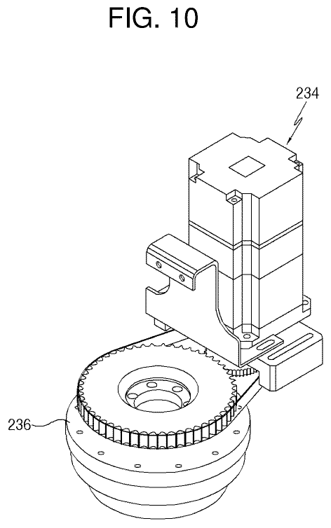

As shown in FIGS. 9 and 10, the first arm drive unit 230 is a component inserted and fixed to the upper end of the lifting shaft 220, is rotatable in the X-axis direction with respect to the center of the lifting shaft 220, and is capable of picking up, withdrawing, transferring, loading, and introducing a heavy-duty probe card. The first arm drive unit 230 includes a first arm drive housing 232, a first arm rotating means 234, the rear-side connection drive 236, and a front-side connection drive 238.

The first arm drive housing 232 is configured such that through-holes are formed in the rear and front portions, respectively, so that the rear-side connection drive 236 and the front-side connection drive 238 are inserted and passed through, in which the rear-side connection drive 236 and the front-side connection drive 238 are configured to be connected to the lifting shaft 220 and an arm connection member 256 of the second arm drive unit 250, respectively.

The first arm drive housing 232 includes the first arm rotating means 234 for rotating the rear-side connection drive 236 and the front-side connection drive 238, and a communication and control unit 242 connected to the drive control unit or a terminal device such as a worker's cell phone or work computer through a wireless network so as to receive a driving control signal of the first arm rotating means 234 and control whether or not to drive the first arm rotating means 234.

In addition, the first arm drive housing 232 may additionally include a lamp unit 244 that emits a predetermined light when the first arm drive unit 230 is driven by the communication and control unit 242 to inform that the first arm drive unit 230 is in operation.

The first arm rotating means 234 may be a known wheel motor, and includes a rear-side arm rotating means 234a connected to the rear-side connection drive 236 by a power providing means such as a belt, and a front-side arm rotating means 234b connected to the front-side connection drive 238.

The rear-side connection drive 236 is connected to the lifting shaft 220 so that the first arm drive unit 230 can be lifted and lowered when the lift shaft 220 is lifted and lowered, and configured to be rotated with respect to the X-axis direction when the rear-side rotating means 234a described above is driven.

The front-side connection drive 238 is configured such that the arm connection member 256 of the second arm drive unit 250 is inserted and fixed therein, and the second arm drive unit 250 may be rotated in the X-axis direction according to whether the front-side arm rotating means 234b is driven.

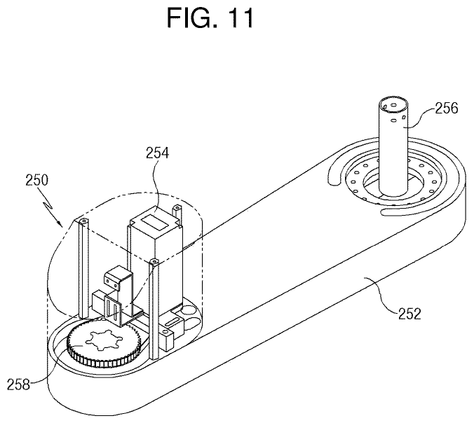

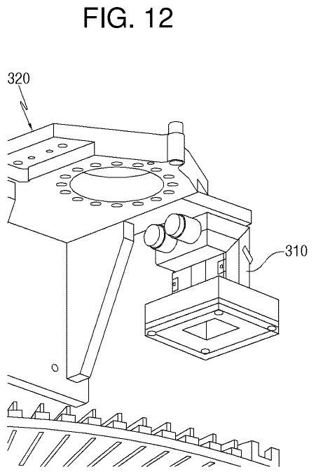

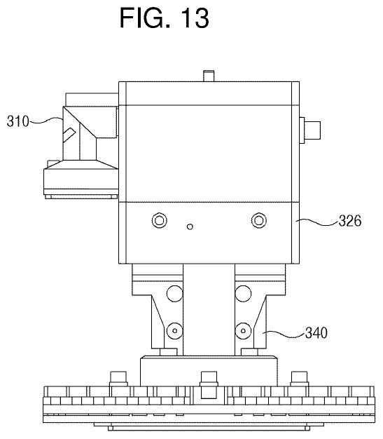

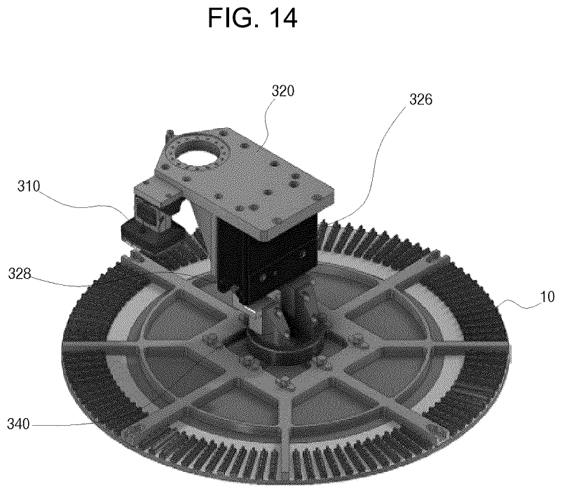

As shown in FIG. 11, the second arm drive unit 250 is connected at a rear portion to the first arm drive unit 230 and connected at a front portion to the gripper unit 300 so as to rotate the gripper unit 300 in the X-axis direction when the first arm drive unit 230 is driven. The second arm drive unit 250 includes a second arm drive housing 252, a second arm rotating means 254, the arm connection member 256, and a gripper connection drive 258.

The second arm drive housing 252 is connected at its rear side with a front-side connection drive 238 of the first arm drive unit 230, and connected with the arm connection member 256 that allows the second arm drive unit 250 to be rotated along the rotational direction of the front-side connection drive 238.

In addition, the second arm drive housing 252 is coupled with the second arm rotation unit 254 that is provided in the front portion of the second arm drive housing 252 and that provides rotational force to rotate a mounting frame 320 of the gripper unit 300 in the X-axis direction, and coupled with the gripper connection drive 258 connected to the second arm rotation unit 254 and the power supply unit, and connected to the mounting frame 320 to rotate the gripper unit 300.

The second arm rotating means 254 may be configured to be driven under the control of the communication and control unit 242 described above.

The gripper unit 300 is rotatably coupled to the second arm drive unit 250, is configured to pick up, withdraw, transfer, load, and introduce a heavy-duty probe card, and includes the vision camera 310, the mounting frame 320, and the gripper 340.

The vision camera 310 is coupled to one side of the mounting frame 320 to determine the gripping position of the gripper 340, and is configured so that the gripper 340 can safely grip the heavy-duty probe card.

The vision camera 310 is configured to determine the gripping position of the gripper 340 while being rotated in the X-axis direction together with the mounting frame 320 by the second arm drive unit 250, and preferably recognize an alignment mark configured on the heavy-duty probe card and transmit the result to the communication and control unit 242 so that the rotation operation of the second arm drive unit 250 and the gripping operation of the gripper unit 300 are performed.

The mounting frame 320 is rotatably coupled to the second arm drive unit 250 and supports the gripper 340 so that the position of the gripper 340 can be moved, and is coupled with the gripper connection drive 258 of the second arm drive unit 250 to be rotated depending on whether the gripper connection drive 258 is operated or not.

In addition, the mounting frame 320 includes a position guide frame 324 coupled to the front end of the mounting frame 320, and includes a position control member 326 mounted on one side to adjust the position of the gripper 340, and a gripper tip 328 slidably coupled to a lower end of the position guide frame 324.

A guide rail groove for guiding the sliding movement of the gripper tip 328 may be formed on the lower end of the position guide frame 324.

The gripper tip 328 may be made of a known rail member and coupled with the gripper 340.

The gripper tip 328 may additionally include a driving means for enabling the sliding movement along the guide rail groove of the position guide frame 324.

The above description is merely illustrative of the technical idea of the present invention, and those of ordinary skill in the art to which the present invention pertains will be able to make various modifications and variations without departing from the essential characteristics of the present invention. Accordingly, the embodiments disclosed in the present invention are not intended to limit the technical idea of the present invention, but to explain the technical idea, and the scope of the technical idea of the present invention is not limited by these embodiments. The scope of protection of the present invention should be interpreted by the following claims, and all technical ideas within the scope equivalent thereto should be construed as being included in the scope of the present invention.

What is claimed is:

1. A heavy-duty probe card transfer and loading device, comprising:
a main body that moves along a set travel route;
a loading arm assembly comprising an up-down unit coupled to the main body and configured to perform a lifting and lowering operation, a first arm drive unit rotatably coupled to the up-down unit, and a second arm drive unit rotatably coupled to the other end of the first arm drive unit; and
a gripper unit rotatably coupled to the second arm drive part to grip a heavy-duty probe card and place the same on the main body.

2. The device according to claim 1, wherein the main body comprises:
a transfer body including a transfer means for moving along the travel route;
a control main body including a driving control unit for controlling driving of the probe card transfer and loading device, and a battery built therein, wherein the loading arm assembly is mounted to the control main body;
a loading top plate coupled to an upper portion of the control main body and supporting the probe card so that the probe card can be seated in position;
a mounting sensor configured on the loading top plate and sensing whether or not the probe card is seated and transmitting the sensed result to a drive control unit; and
a charging unit formed on the control main body unit and configured to allow electrical connection of the battery and the docking device.

3. The device according to claim 2, wherein the control main body comprises:
a safety laser sensor that recognizes an obstacle and allows the driving to be performed while avoiding the recognized obstacle; and
a load arm motion search unit that senses whether the load arm assembly is operated or not so that an operating state of the load arm assembly can be determined.

4. The device according to claim 3, wherein the control main body further comprises:
a drive control unit that analyzes information transmitted from the safety laser sensor and the load arm motion search unit to generate route information about positions for withdrawing and replacing the probe card, and a transfer position for transferring the withdrawn probe card; and
an operating module that transmits a control signal for controlling the driving of the probe card transfer and loading device to the drive control unit.

5. The device according to claim 1, wherein the up-down unit comprises:
a lifting motor driven under the control of a drive control unit;
a ball screw lifted and lowered when the lifting motor is driven;
a lifting guide panel lifted and lowered when the ball screw is operated and including a lifting shaft configured at an upper central portion and connected to the first arm drive unit; and
an LM guide member that guides the lifting and lowering of the lifting guide panel when the ball screw is operated.

6. The device according to claim 1, wherein the first arm drive unit comprises:
a first arm drive housing configured with a communication and control unit;
a first arm rotating means configured in front and rear portions of the first arm drive housing and connected to the second arm drive unit and the up-down unit, respectively;
a rear-side connection drive rotatably connected to the first arm rotating unit and rotating the first arm drive housing; and
a front-side connection drive rotatably connected to the first arm rotating unit and rotating the second arm drive unit.

7. The device according to claim 6, wherein the second arm drive unit comprises:
a second arm drive housing;
an arm connection member formed at a rear portion of the second arm drive housing and connected to the rear-side connection drive;
a gripper connection drive formed on a front portion of the second arm drive housing and to which the gripper unit is rotatably coupled; and
a second arm rotating means for rotating the gripper connection drive.

8. The device according to claim 1, wherein the gripper unit comprises:
a gripper that grips the heavy-duty probe card;
a mounting frame rotatably coupled to the second arm drive unit; and
a vision camera coupled to the mounting frame and determining a gripping position of the gripper.

9. The device according to claim 8, wherein the mounting frame comprises:
a position guide frame coupled to a front side end and mounted with a position control member that adjusts the position of the gripper; and
a gripper tip slidably coupled to a lower end of the position guide frame and to which the gripper is coupled.
